(19) United States
(12) Patent Application Publication
(10) Pub. No.: US 2024/0339970 A1
(43) Pub. Date: Oct. 10, 2024

(54) Audio processing apparatus and method having noise reducing mechanism

(71) Applicant: REAL TEK SEMICONDUCTOR CORPORATION, HSINCHU (TW)

(72) Inventor: CHUN-I KUO, Hsinchu (TW)

(21) Appl. No.: 18/610,313

(22) Filed: Mar. 20, 2024

(30) Foreign Application Priority Data
Apr. 7, 2023 (TW) 112113173

(51) Int. Cl. H03F 3/217

(52) U.S. Cl. CPC H03F 3/2175; H03F 2200/345; H03F 2200/351

(57) ABSTRACT

The present disclosure discloses an audio processing apparatus having noise reducing mechanism. A DSP circuit generates N-bit digital audio signal, N being an integer larger than 1. A first modulation circuit truncates the digital audio signal and performs a first modulation processing based on pulse width or pulse density modulation to generate a single-bit waveform modulated signal. An amplifier includes a single-bit DAC circuit, a second modulation circuit and a driving circuit. The single-bit DAC circuit converts the single-bit waveform modulated signal to generate an input analog signal. The second modulation circuit subtracts the input analog signal and an output modulated signal to generate a subtraction result and performs a second modulation processing thereon to generate a control signal. The driving circuit generates the output modulation signal according to the control signal and transmits the output modulation signal to the second modulation circuit through a closed-loop feedback path.

### BACKGROUND OF THE INVENTION

### 1. Field of the Invention

The present disclosure relates to an audio processing apparatus and an audio processing method having noise reducing mechanism.

### 2. Description of Related Art

An audio processing apparatus includes a digital block and an analog block. The digital block converts high precision data to an over-sampled and low precision digital signal such that the analog block performs digital-to-analog conversion and filtering on the digital signal for an amplifier circuit to amplify the processed result and playback by the speaker.

In recent years, the demand on the processing ability to reduce the noise becomes higher due to the popularity of consumer products such as Bluetooth earphones. However, in conventional technologies, the demand is usually satisfied at the cost of area and power consumption, which is not beneficial for devices like portable Bluetooth earphones. Though dynamic range enhancement can be used to reduce the noise, such a technology affects the dynamic headroom of the signal.

### SUMMARY OF THE INVENTION

In consideration of the problem of the prior art, an object of the present disclosure is to provide an audio processing apparatus and an audio processing method having noise reducing mechanism.

The present invention discloses an audio processing apparatus having noise reducing mechanism that includes a digital processing circuit, a first modulation circuit, and an amplifier circuit. The digital processing circuit is configured to generate an N-bit digital audio signal, N being an integer larger than 1. The first modulation circuit is configured to truncate the digital audio signal and perform a first modulation processing based on pulse width modulation or pulse density modulation to generate a single-bit waveform modulated signal. The amplifier circuit includes a single-bit digital-to-analog conversion (DAC) circuit, a second modulation circuit and a driving circuit. The single-bit digital-to-analog conversion circuit is configured to receive and convert the single-bit waveform modulated signal to generate an input analog signal. The second modulation circuit is configured to receive the input analog signal and an output modulated signal, perform subtraction thereon to generate a subtracted result and perform a second modulation processing based on pulse width or pulse density modulation to generate a control signal. The driving circuit is configured to generate the output modulation signal according to the control signal and transmit the output modulation signal to the second modulation circuit through a closed-loop feedback path.

The present invention also discloses an audio processing method having noise reducing mechanism that includes steps outlined below. An N-bit digital audio signal is generated by a digital processing circuit, N being an integer larger than 1. The digital audio signal is truncated and a first modulation processing is performed based on pulse width modulation or pulse density modulation by a first modulation circuit to generate a single-bit waveform modulated signal. The single-bit waveform modulated signal is received and converted by a single-bit digital-to-analog conversion circuit of an amplifier circuit to generate an input analog signal. The input analog signal and an output modulated signal are received, subtraction is performed thereon to generate a subtracted result and a second modulation processing is performed based on pulse width or pulse density modulation by a second modulation circuit of the amplifier circuit to generate a control signal. The output modulation signal is generated according to the control signal and the output modulation signal is transmitted to the second modulation circuit through a closed-loop feedback path by a driving circuit of the amplifier circuit.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a block diagram of an audio processing apparatus having noise reducing mechanism according to an embodiment of the present invention.

FIG. 2 illustrates a more detailed circuit diagram of the amplifier circuit according to an embodiment of the present invention.

FIG. 3 illustrates a more detailed circuit diagram of the amplifier circuit according to another embodiment of the present invention.

FIG. 4 illustrates a flow chart of an audio processing method having noise reducing mechanism according to an embodiment of the present invention.

### DETAILED DESCRIPTION OF THE PREFERRED EMBODIMENTS

An aspect of the present invention is to provide an audio processing apparatus and an audio processing method having noise reducing mechanism to perform modulation by using a first modulation circuit to output a single-bit waveform modulated signal such that an amplifier circuit may adapt a single-bit DAC circuit having small area and low power consumption to perform conversion and further use a closed-loop feedback circuit configuration to remove the noise. The demand of small area, low power consumption and noise reduction can be maintained at the same time under the condition that a larger dynamic range of the signal can be processed.

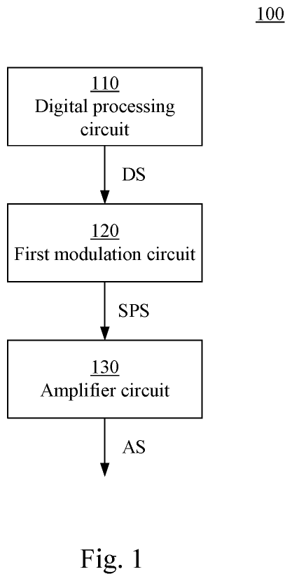

Reference is now made to FIG. 1. FIG. 1 illustrates a block diagram of an audio processing apparatus 100 having noise reducing mechanism according to an embodiment of the present invention. The audio processing apparatus 100 includes a digital processing circuit 110, a first modulation circuit 120 and an amplifier circuit 130.

The digital processing circuit 110 is configured to generate an N-bit digital audio signal DS, N being an integer larger than 1. In an embodiment, the digital audio signal DS can be a 24-bit digital signal.

The first modulation circuit 120 is configured to truncate the digital audio signal DS and perform a first modulation processing based on pulse width modulation or pulse density modulation to generate a single-bit waveform modulated signal SPS.

More specifically, the first modulation processing performed by the first modulation circuit 120 can be either the pulse width modulation (PWM) or the pulse density modulation (PDM) to truncate and modulate the digital audio signal DS having a number of bits larger than 1 to generate the single-bit waveform modulated signal SPS that is still in the digital form and has a number of bit of 1.

In an embodiment, the first modulation circuit 120 can be such as, but not limited to a sigma-delta modulator circuit having an order of five to truncate and modulate the 24-bit digital audio signal DS into the 1-bit single-bit waveform modulated signal SPS.

In the components described above, the signals processed and generated by the digital processing circuit 110 and the first modulation circuit 120 are all in the digital form. The amplifier circuit 130 is configured to further perform digital-to-analog conversion, filtering, modulation and amplification on the single-bit waveform modulated signal SPS to generate an output modulated signal AS.

In an embodiment, the amplifier circuit 130 is such as, but not limited to a class-D amplifier. The output modulated signal AS generated by the amplifier circuit 130 is a modulated signal in the digital form that simulates an analog output to be outputted to a load such as a speaker to be playback. The load can be equivalent to a low-pass filtering circuit including inductors and resistors to restore the output modulated signal AS to a form close to a sine wave so as to be perceived by human ears.

The configuration and operation of the amplifier circuit 130 are described in detail in the following paragraphs.

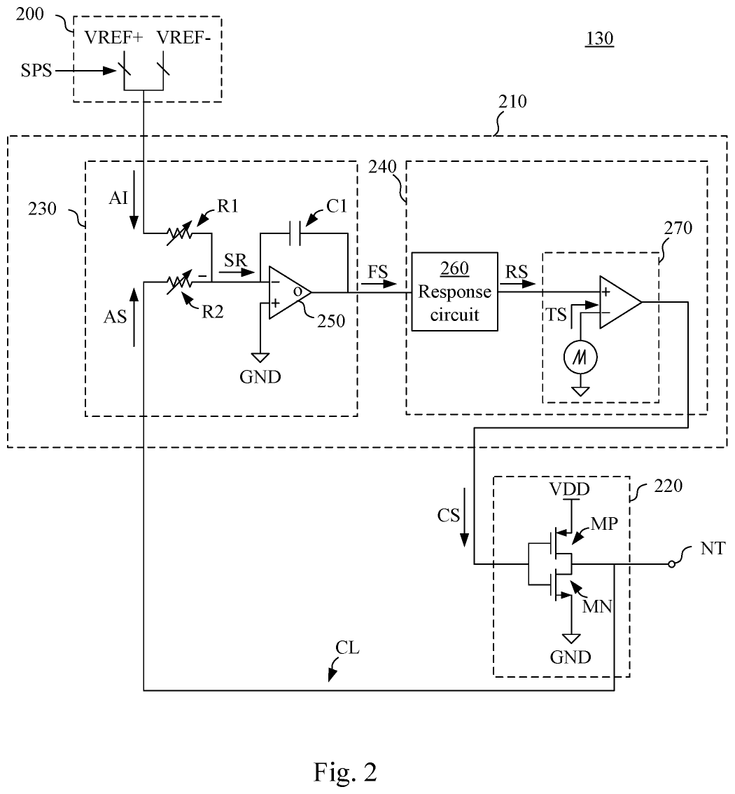

Reference is now made to FIG. 2. FIG. 2 illustrates a more detailed circuit diagram of the amplifier circuit 130 according to an embodiment of the present invention.

The amplifier circuit 130 includes a single-bit DAC circuit 200, a second modulation circuit 210 and a driving circuit 220.

The single-bit DAC circuit 200 is configured to receive and convert the single-bit waveform modulated signal SPS to generate an input analog signal AI.

In an embodiment, the single-bit DAC circuit 200 is a switch circuit configured to switch to output one of a first reference voltage VREF+ and a second reference voltage VREF− as the input analog signal AI according to the single-bit waveform modulated signal SPS.

For example, when the single-bit waveform modulated signal SPS is at a high state, the single-bit DAC circuit 200 switches to be coupled to a voltage source providing the first reference voltage VREF+ and outputs the first reference voltage VREF+. When the single-bit waveform modulated signal SPS is at a low state, the single-bit DAC circuit 200 switches to be coupled to a voltage source providing the second reference voltage VREF− and outputs the second reference voltage VREF−.

In a numerical example, the first reference voltage VREF+ is 1.8 volts and the second reference voltage VREF− is 0 volt. However, the present invention is not limited thereto.

In general, a digital-to-analog conversion circuit having multiple bits is configured with a switch capacitor array and an operational amplifier that have large area and large power consumption. However, since the amplifier circuit 130 in the present invention only receives a single-bit input, the single-bit DAC circuit 200 that is simplified to have small area and small power consumption can be used.

Moreover, the single-bit waveform modulated signal SPS generated after the conversion is not used to directly drive a heavier load (i.e., a load having a smaller resistance). Instead, the second modulation circuit 210 and the driving circuit 220 in the back end are used to drive such a load. As a result, the first reference voltage VREF+ and the second reference voltage VREF− can be provided by cleaner voltage sources to accomplish a better conversion result.

The second modulation circuit 210 is configured to receive the input analog signal AI and the output modulated signal AS, perform subtraction thereon to generate a subtracted result SR, and perform a second modulation processing on the subtracted result SR based on pulse width or pulse density modulation to generate a control signal CS.

Preferably, the first modulation processing performed by the first modulation circuit 120 and the second modulation processing performed by the second modulation circuit 210 are the same modulation processing, e.g., both are pulse width modulation or both are pulse density modulation.

The second modulation circuit 210 includes a front-end integral filter circuit 230 and a back-end modulation circuit 240.

The front-end integral filter circuit 230 is configured to receive the input analog signal AI and the output modulated signal AS, perform subtraction thereon to generate the subtracted result SR and perform low-pass filtering and integration on the subtracted result SR to generate a filtered signal FS. In an embodiment, the front-end integral filter circuit 230 includes a comparison circuit 250, a capacitor C1, a first input resistor R1 and a second input resistor R2.

The comparison circuit 250 is configured to receive the subtracted result SR between the input analog signal AI and the output modulated signal AS from the first input terminal and receive a ground voltage GND from the second input terminal, so as to perform comparison on the subtracted result SR and the ground voltage GND and generate the filtered signal FS at an output terminal.

In an embodiment, the first input terminal of the comparison circuit 250 is an inverted input terminal labeled by a symbol “−”. The second input terminal of the comparison circuit 250 is a non-inverted input terminal labeled by a symbol “+”. The output terminal of the comparison circuit 250 is labeled by a symbol “o”.

The capacitor C1 is electrically coupled to the first input terminal and the output terminal of the comparison circuit 250. The first input resistor R1 is configured to receive and feed the input analog signal AI to the first input terminal of the comparison circuit 250. The second input resistor R2 is configured to receive and feed the output modulated signal AS to the first input terminal, so as to be subtracted with the input analog signal AI fed to the first input terminal to generate the subtracted result SR.

In different embodiments, the subtraction between the input analog signal AI and the output modulated signal AS may be performed by using a subtract circuit at the first input terminal or by using other mechanisms. In FIG. 2, a symbol of “−” is illustrated at a position that the second input resistor R2 is coupled to the first input terminal to represent the subtraction of the two signals without illustrating any hardware circuit actually used to perform subtraction.

In an embodiment, each of the first input resistor R1 and the second input resistor R2 is a variable resistor, and each of the resistance of the first input resistor R1 and the second input resistor R2 is configured to determine a gain of each of the input analog signal AI and the output modulated signal AS.

As a result, by using the configuration described above, the front-end integral filter circuit 230 performs low-pass filtering and integration on the subtracted result SR to generate the filtered signal FS.

The back-end modulation circuit 240 is configured to modulate the filtered signal FS to generate the control signal CS. According to different waveform modulation mechanism that the second modulation circuit 210 performs, the back-end modulation circuit 240 may include different configurations.

In an embodiment, the second modulation processing performed by the second modulation circuit 210 is performed based on the pulse width modulation. Under such a condition, the back-end modulation circuit 240 included by the second modulation circuit 210 may include a response circuit 260 and a modulated signal generation circuit 270 as illustrated in FIG. 2.

The response circuit 260 is configured to perform frequency response processing on the filtered signal FS to generate a response signal RS. The modulated signal generation circuit 270 is configured to perform comparison on the response signal RS and a triangle wave signal TS to generate the control signal CS. In an embodiment, the response signal RS generated by the response circuit 260 is still a continuous signal, in which the control signal CS generated by the modulated signal generation circuit 270 is a discrete signal.

The driving circuit 220 is configured to generate the output modulated signal AS according to the control signal CS and transmit the output modulated signal AS to the second modulation circuit 210 through a closed-loop feedback path CL.

In an embodiment, driving circuit 220 includes a P-type transistor MP and an N-type transistor MN. The P-type transistor MP is electrically coupled between a supply power VDD and a connection terminal NT. The N-type transistor MN is electrically coupled between the connection terminal NT and the ground voltage GND.

The P-type transistor MP and the N-type transistor MN are controlled by the control signal CS to generate the output modulated signal AS at the connection terminal NT. As a result, the closed-loop feedback path CL couples the connection terminal NT and the second input resistor R2 such that the output modulated signal AS is transmitted to the second input resistor R2 through the closed-loop feedback path CL.

Therefore, by using the closed-loop feedback path CL, the second modulation circuit 210 and driving circuit 220 form a feedback mechanism, such that the comparison circuit 250 performs comparison on the subtracted result SR and the ground voltage GND that is 0 volt. After the subtracted result SR between the input analog signal AI in the sine wave form and the output modulated signal AS in the square wave form is compared with the ground voltage GND, the filtered signal FS is generated based on the integral characteristic of the front-end integral filter circuit 230.

The output modulated signal AS approximates the input analog signal AI due to the mechanism described above. The noise fed to driving circuit 220 is cancelled by itself due to the feedback mechanism and the low-pass filtering effect to decrease the impact thereof on the frequency band that the output modulated signal AS locates.

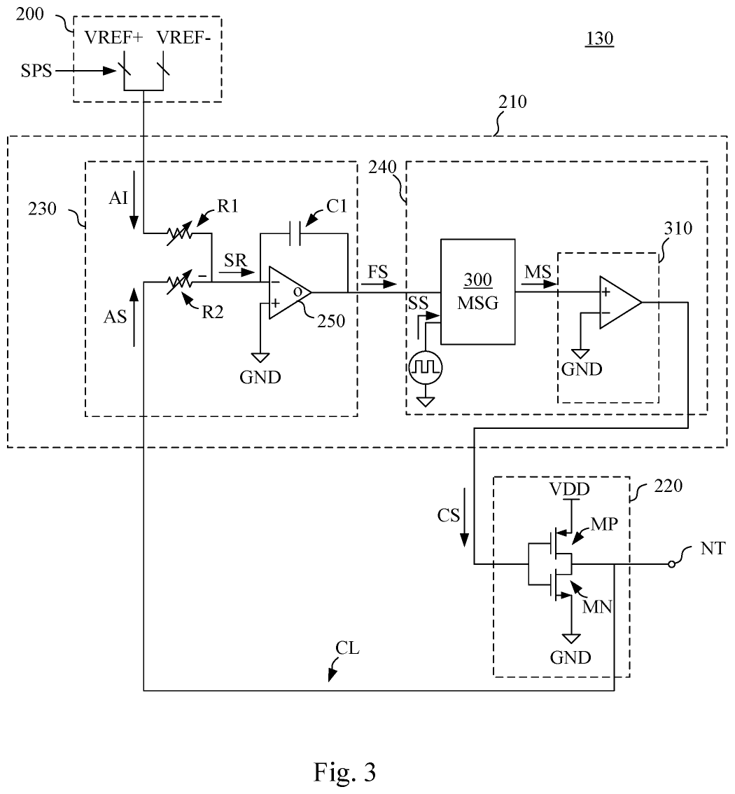

Reference is now made to FIG. 3. FIG. 3 illustrates a more detailed circuit diagram of the amplifier circuit 130 according to another embodiment of the present invention. The configuration and operation of the amplifier circuit 130 in FIG. 3 are similar to those in FIG. 2. As a result, the identical components are not described in the following paragraphs. In FIG. 3, the second modulation processing performed by the second modulation circuit 210 included by the amplifier circuit 130 is performed based on the pulse density modulation. Under such a condition, the back-end modulation circuit 240 included by the second modulation circuit 210 may include a modulated signal generation circuit 300 (abbreviated as MSG in FIG. 3) and a comparison circuit 310 as illustrated in FIG. 3.

The modulated signal generation circuit 300 is configured to modulate the filtered signal FS according to a square wave signal SS to generate a modulated signal MS. In an embodiment, the modulated signal generation circuit 300 is a switched-capacitor sigma-delta modulator circuit.

The comparison circuit 310 is configured to perform comparison on the modulated signal MS and the ground voltage GND to generate the control signal CS.

In some approaches, the audio playback apparatus needs a digital-to-analog conversion circuit and an amplifier circuit having larger area and larger power consumption to process the audio and lower the noise. Under the condition that the demand of the signal-to-noise ration is higher, a dynamic range enhancement (DRE) technology is further required to accomplish the noise reduction mechanism. However, the dynamic range enhancement technology affects the dynamic headroom of the signal such that the signal having an intensity larger than a predetermined value can not be received.

The audio processing apparatus 100 having noise reducing mechanism of the present invention performs modulation by using a first modulation circuit to output a single-bit waveform modulated signal such that an amplifier circuit may adapt a single-bit DAC circuit having small area and low power consumption to perform conversion and further use a closed-loop feedback circuit configuration to remove the noise. The demand of small area, low power consumption and noise reduction can be maintained at the same time under the condition that a larger dynamic range of the signal can be processed.

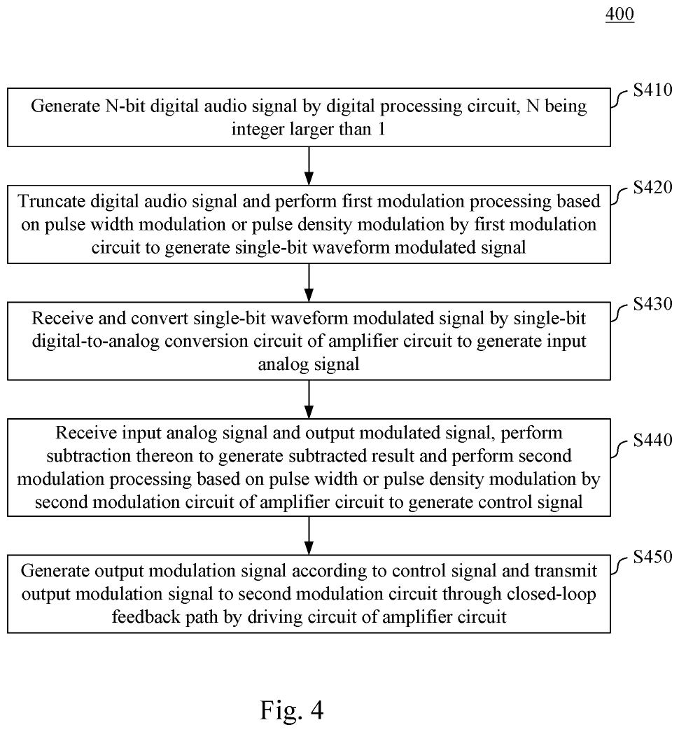

Reference is now made to FIG. 4. FIG. 4 illustrates a flow chart of an audio processing method 400 having noise reducing mechanism according to an embodiment of the present invention.

Besides the apparatus described above, the present invention further discloses the audio processing method 400 that can be used in such as, but not limited to the audio processing apparatus 100 illustrated in FIG. 1. An embodiment of the audio processing method 400 is illustrated in FIG. 4 and includes the steps outlined below.

In step S410, the N-bit digital audio signal DS is generated by the digital processing circuit 110, N being an integer larger than 1.

In step S420, the digital audio signal DS is truncated and the first modulation processing is performed based on pulse width modulation or pulse density modulation by the first modulation circuit 120 to generate the single-bit waveform modulated signal SPS.

In step S430, the single-bit waveform modulated signal SPS is received and converted by the single-bit digital-to-analog conversion circuit 200 of the amplifier circuit 130 to generate the input analog signal AI.

In step S440, the input analog signal AI and the output modulated signal AS are received, subtraction is performed thereon to generate the subtracted result SR and the second modulation processing is performed based on pulse width or pulse density modulation by the second modulation circuit 210 of the amplifier circuit 130 to generate the control signal CS.

In step S450, the output modulation signal AS is generated according to the control signal CS and the output modulation signal AS is transmitted to the second modulation circuit 210 through the closed-loop feedback path CL by the driving circuit 220 of the amplifier circuit 130.

It is appreciated that the embodiments described above are merely an example. In other embodiments, it is appreciated that many modifications and changes may be made by those of ordinary skill in the art without departing, from the spirit of the invention.

In summary, the audio processing apparatus and the audio processing method having noise reducing mechanism of the present invention perform modulation by using a first modulation circuit to output a single-bit waveform modulated signal such that an amplifier circuit may adapt a single-bit DAC circuit having small area and low power consumption to perform conversion and further use a closed-loop feedback circuit configuration to remove the noise. The demand of small area, low power consumption and noise reduction can be maintained at the same time under the condition that a larger dynamic range of the signal can be processed.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. An audio processing apparatus having noise reducing mechanism, comprising:
a digital processing circuit configured to generate an N-bit digital audio signal, N being an integer larger than 1;
a first modulation circuit configured to truncate the digital audio signal and perform a first modulation processing based on pulse width modulation or pulse density modulation to generate a single-bit waveform modulated signal; and
an amplifier circuit comprising:
a single-bit digital-to-analog conversion (DAC) circuit configured to receive and convert the single-bit waveform modulated signal to generate an input analog signal;
a second modulation circuit configured to receive the input analog signal and an output modulated signal, perform subtraction thereon to generate a subtracted result and perform a second modulation processing on the subtracted result based on pulse width or pulse density modulation to generate a control signal; and
a driving circuit configured to generate the output modulation signal according to the control signal and transmit the output modulation signal to the second modulation circuit through a closed-loop feedback path.

2. The audio processing apparatus of claim 1, wherein the single-bit DAC circuit is a switch circuit configured to switch to output one of a first reference voltage and a second reference voltage as the input analog signal according to the single-bit waveform modulated signal.

3. The audio processing apparatus of claim 1, wherein the second modulation circuit comprises:
a front-end integral filter circuit configured to receive the input analog signal and the output modulated signal, perform subtraction thereon to generate the subtracted result and perform low-pass filtering and integration on the subtracted result to generate a filtered signal; and
a back-end modulation circuit configured to modulate the filtered signal to generate the control signal.

4. The audio processing apparatus of claim 3, wherein the front-end integral filter circuit comprises:
a comparison circuit configured to receive the subtracted result from a first input terminal and receive a ground voltage from a second input terminal, so as to perform comparison on the subtracted result and the ground voltage and generate the filtered signal at an output terminal;
a capacitor electrically coupled to the first input terminal and the output terminal;
a first input resistor configured to receive and feed the input analog signal to the first input terminal; and
a second input resistor configured to receive and feed the output modulated signal to the first input terminal, so as to be subtracted with the input analog signal fed to the first input terminal to generate the subtracted result.

5. The audio processing apparatus of claim 4, wherein each of the first input resistor and the second input resistor is a variable resistor, and each of the resistance of the first input resistor and the second input resistor is configured to determine a gain of each of the input analog signal and the output modulated signal.

6. The audio processing apparatus of claim 3, wherein the second modulation processing is performed based on the pulse width modulation, and the back-end modulation circuit comprises:
a response circuit configured to perform frequency response processing on the filtered signal to generate a response signal; and
a modulated signal generation circuit configured to perform comparison on the response signal and a triangle wave signal to generate the control signal.

7. The audio processing apparatus of claim 3, wherein the second modulation processing is performed based on the pulse density modulation, and the back-end modulation circuit comprises:
a modulated signal generation circuit configured to modulate the filtered signal according to a square wave signal to generate a modulated signal; and
a comparison circuit configured to perform comparison on the modulated signal and a ground voltage to generate the control signal.

8. The audio processing apparatus of claim 7, wherein the modulated signal generation circuit is a switched-capacitor sigma-delta modulator circuit.

9. The audio processing apparatus of claim 1, wherein the driving circuit comprises:
a P-type transistor electrically coupled between a supply power and a connection terminal; and
a N-type transistor electrically coupled between the connection terminal and a ground voltage;
wherein the P-type transistor and the N-type transistor are controlled by the control signal to generate the output modulated signal at the connection terminal.

10. An audio processing method having noise reducing mechanism, comprising:
generating an N-bit digital audio signal by a digital processing circuit, N being an integer larger than 1;
truncating the digital audio signal and performing a first modulation processing based on pulse width modulation or pulse density modulation by a first modulation circuit to generate a single-bit waveform modulated signal;
receiving and converting the single-bit waveform modulated signal by a single-bit digital-to-analog conversion circuit of an amplifier circuit to generate an input analog signal;
receiving the input analog signal and an output modulated signal, performing subtraction thereon to generate a subtracted result and performing a second modulation processing on the subtracted result based on pulse width or pulse density modulation by a second modulation circuit of the amplifier circuit to generate a control signal; and
generating the output modulation signal according to the control signal and transmitting the output modulation signal to the second modulation circuit through a closed-loop feedback path by a driving circuit of the amplifier circuit.

11. The audio processing method of claim 10, wherein the single-bit DAC circuit is a switch circuit, the audio processing method further comprises:
switching to output one of a first reference voltage and a second reference voltage as the input analog signal according to the single-bit waveform modulated signal by the switch circuit.

12. The audio processing method of claim 10, further comprising:
receiving the input analog signal and the output modulated signal, performing subtraction thereon to generate the subtracted result and performing low-pass filtering and integration on the subtracted result to generate a filtered signal by a front-end integral filter circuit of the second modulation circuit; and
modulating the filtered signal to generate the control signal by a back-end modulation circuit of the second modulation circuit.

13. The audio processing method of claim 12, further comprising:
receiving the subtracted result from a first input terminal and receiving a ground voltage from a second input terminal by a comparison circuit of the front-end integral filter circuit, so as to perform comparison on the subtracted result and the ground voltage and generate the filtered signal at an output terminal;
electrically coupling a capacitor of the front-end integral filter circuit to the first input terminal and the output terminal;
receiving and feeding the input analog signal to the first input terminal by a first input resistor of the front-end integral filter circuit; and
receiving and feeding the output modulated signal to the first input terminal by a second input resistor of the front-end integral filter circuit, so as to be subtracted with the input analog signal fed to the first input terminal to generate the subtracted result.

14. The audio processing method of claim 13, wherein each of the first input resistor and the second input resistor is a variable resistor, and each of the resistance of the first input resistor and the second input resistor is configured to determine a gain of each of the input analog signal and the output modulated signal.

15. The audio processing method of claim 12, wherein the second modulation processing is performed based on the pulse width modulation, and the audio processing method further comprises:
performing response processing on the filtered signal to generate a response signal by a response circuit of the back-end modulation circuit; and
performing comparison on the response signal and a triangle wave signal to generate the control signal by a modulated signal generation circuit of the back-end modulation circuit.

16. The audio processing method of claim 12, wherein the second modulation processing is performed based on the pulse density modulation, and the audio processing method further comprises:
modulating the filtered signal according to a square wave signal to generate a modulated signal by a modulated signal generation circuit of the back-end modulation circuit; and
performing comparison on the modulated signal and a ground voltage to generate the control signal by a comparison circuit of the back-end modulation circuit.

17. The audio processing method of claim 16, wherein the modulated signal generation circuit is a switched-capacitor sigma-delta modulator circuit.

18. The audio processing method of claim 10, further comprising:
electrically coupling a P-type transistor of the driving circuit between a supply power and a connection terminal; and
electrically coupling a N-type transistor of the driving circuit between the connection terminal and a ground voltage;
controlling the P-type transistor and the N-type transistor by the control signal to generate the output modulated signal at the connection terminal.
